(19) United States
(12) Patent Application Publication
(10) Pub. No.: US 2006/0138534 A1
(43) Pub. Date: Jun. 29, 2006

(54) Nonvolatile memory device, method for fabricating the same, and method for programming/erasing data in the same

(75) Inventor: Heung Jin Kim, Eumseong-gun (KR)

Correspondence Address: MCKENNA LONG & ALDRIDGE LLP, 1900 K STREET, NW, WASHINGTON, DC, 20006, US

(73) Assignee: DongbuAnam Semiconductor Inc., Seoul (KR)

(21) Appl. No.: 11/318,578

(22) Filed: Dec. 28, 2005

(30) Foreign Application Priority Data
Dec. 29, 2004 (KR) P-2004-0114612

(51) Int. Cl. H01L 29/94

(52) U.S. Cl. 257/330

(57) ABSTRACT

A nonvolatile memory device, a method for fabricating the same, and a method for programming/erasing data in the same are provided. At least one of a plurality of device isolation films is filled with polysilicon and used as an acceleration line. The nonvolatile memory device includes a semiconductor substrate defined by a plurality of device isolation regions and an active region, a first electrode layer formed in the at least one device isolation region of the plurality of device isolation regions, an isolation insulating layer filled in the other device isolation region of the plurality of device isolation regions, junction regions formed in a predetermined portion of the active region, a gate insulating film formed on the semiconductor substrate including the plurality of device isolation regions and the junction regions, a tunnel oxide film formed by selectively etching the gate insulating film, and a second electrode layer formed on the gate insulating film to partially overlap the junction regions.

### CROSS-REFERENCE TO RELATED APPLICATION

This application claims the benefit of Korean Patent Application No. P2004-114612, filed on Dec. 29, 2004, which is hereby incorporated by reference as if fully set forth herein.

### BACKGROUND OF THE INVENTION

1. Field of the Invention

The present invention relates to a nonvolatile semiconductor memory device, and more particularly, to an electrical erasable programmable read only memory (EEPROM) in which some of a plurality of device isolation films is filled with polysilicon and used as an acceleration line.

2. Discussion of the Related Art

Generally, an EEPROM device stores one bit or a multi bit using one cell, and is a memory device that electrically programs and erases data.

In the EEPROM device, a floating-gate tunnel oxide type EEPROM device programs data using a hot electron through an external high voltage and erases data using fowler-nordheim tunneling. A conventional art EEPROM device includes a floating gate electrode formed on a tunnel oxide film, and a control gate electrode formed on the floating gate electrode and applied with a predetermined voltage.

The conventional EEPROM device is classified as a single poly EEPROM device or a double poly EEPROM device, depending on the fabricating technology and the number of polysilicon layers.

Hereinafter, a method for fabricating a conventional single poly EEPROM device will be described with reference to the accompanying drawings.

FIG. 1 is a sectional view illustrating a conventional single poly EEPROM device.

First, a substrate 10 is prepared, in which a first type well, for example, a P type well is defined. Subsequently, after a predetermined region on the substrate 10 is removed by a local oxidation of silicon (LOCOS) process or a shallow trench isolation (STI) process, the removed region is filled with insulating layers 17 to form device isolation regions 11.

Then, second type ions, for example, N+ type ions, are implanted into a predetermined portion of an active region between the device isolation regions 11 using a predetermined mask to form junction regions 12. At this time, the mask used for ion implantation is removed, and the substrate 10 is annealed to activate the ions implanted into the junction regions 12.

Next, a gate insulating film 13 is deposited on the substrate 10, including the junction regions 12, and a predetermined portion of the gate insulating film 13 is selectively wet-etched to form a tunnel oxide film 14.

Afterwards, polysilicon is deposited on the gate insulating film 13, including the tunnel oxide film 14, and then selectively etched to form a floating gate 15a. In this case, the floating gate 15a is formed to cover the tunnel oxide film 14. A gate 15b of an active transistor is also formed when the polysilicon is etched to form the floating gate 15a.

Subsequently, second type ions, for example, N type ions are implanted into the floating gate 15a and the active transistor 15b.

In the method for fabricating the conventional EEPROM device, the junction regions are separately used to control an erase mechanism, and the floating gate has a large area to increase a voltage level coupled to the floating gate, thereby failing to reduce a size of a cell.

Furthermore, since erasing is performed only in a positive manner, a high voltage is applied to the junction regions during programming or erasing. Therefore, the junction regions need internal pressure for voltage drop because of leakage and high breakdown voltage. Since this method fails to reduce the size of the cell, integration and minimization for the device is limited.

### SUMMARY OF THE INVENTION

Accordingly, the present invention is directed to a nonvolatile memory device, a method for fabricating the same, and a method for programming/erasing data in the same, which substantially obviate one or more problems due to limitations and disadvantages of the related art.

The present invention provides a nonvolatile memory device, a method for fabricating the same, and a method for programming/erasing data in the same, in which some of a plurality of device isolation films is filled with polysilicon and used as an acceleration line.

Additional advantages and features of the invention will be set forth in the description which follows and will become apparent to those having ordinary skill in the art upon examination of the following. These and other advantages of the invention may be realized and attained by the structure particularly pointed out in the written description and claims hereof as well as the appended drawings.

To achieve these and other advantages and in accordance with the invention, as embodied and broadly described herein, a nonvolatile memory device according to the present invention includes a semiconductor substrate defined by a plurality of device isolation regions and an active region, a first electrode layer formed in at least one device isolation region of the plurality of device isolation regions, an isolation insulating layer filled in the at least one device isolation region of the plurality of device isolation regions, junction regions formed in a predetermined portion of the active region, a gate insulating film formed on the semiconductor substrate including the plurality of device isolation regions and the junction regions, a tunnel oxide film formed by selectively etching the gate insulating film, and a second electrode layer formed on the gate insulating film to partially overlap the junction regions.

The second electrode layer includes a floating gate formed on the gate insulating film to overlap the first electrode layer and the junction regions, and an access gate formed on the gate insulating film spaced apart from the floating gate and partially overlapping the junction regions. At this time, the floating gate, the junction region overlapped with the floating gate, and the first electrode layer are operated as a sense transistor. The access gate and the junction region overlapped with the access gate are operated as an access transistor.

In another aspect of the present invention, a method for fabricating a nonvolatile memory device comprises forming a plurality of device isolation regions by selectively etching a predetermined portion of a semiconductor substrate, so as to define the plurality of device isolation regions and an active region, forming a first electrode layer by filling polysilicon in some device isolation region of the plurality of device isolation regions, filling an isolation oxide film in the other device isolation region, forming junction regions in a predetermined portion of the active region, forming a gate insulating film on the semiconductor substrate including the plurality of device isolation regions and the junction regions, forming a tunnel oxide film by selectively etching the gate insulating film, and forming a second electrode layer on the gate insulating film.

The step of forming the second electrode layer includes depositing an electrode material on the gate insulating film, and selectively removing the gate insulating film partially overlapped with the junction region and the first electrode layer to form the second electrode layer.

In other aspect of the present invention, a method for programming/erasing data in the nonvolatile memory device is characterized in that the first electrode layer is used as an acceleration line so that a negative voltage or a positive voltage is applied to the first electrode layer to program or erase predetermined data.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate exemplary embodiments of the invention and together with the description serve to explain the invention. In the drawings:

FIG. 1 is a sectional view illustrating a conventional EEPROM device;

FIG. 2 is a sectional view illustrating an EEPROM device according to an exemplary embodiment of the present invention; and

FIG. 3A to FIG. 3D are sectional views illustrating an EEPROM device fabricated using a method according to an exemplary embodiment of the present invention.

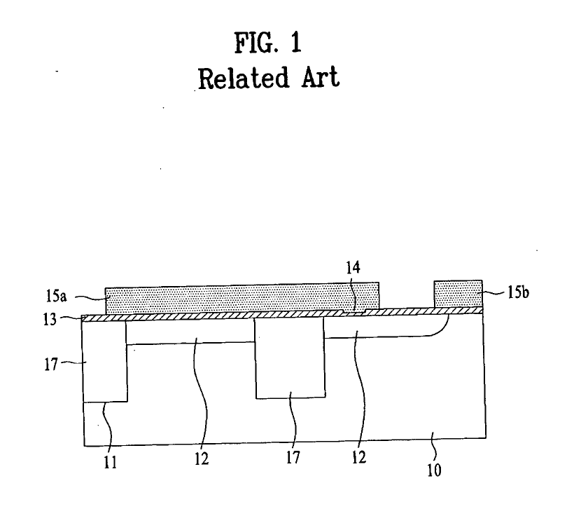

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

An exemplary EEPROM device and a method for fabricating the same will be described with reference to the accompanying drawings.

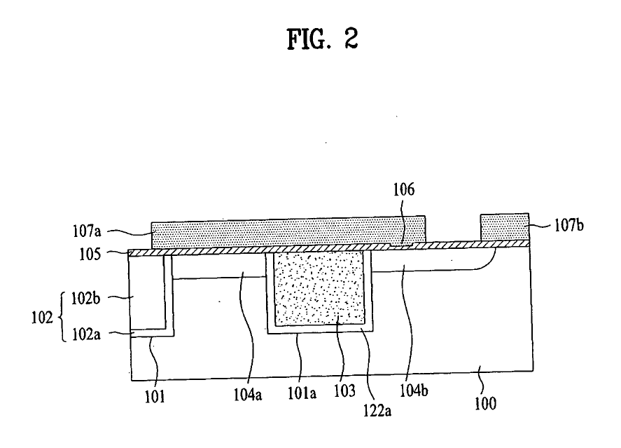

FIG. 2 is a sectional view illustrating an EEPROM device according to an exemplary embodiment of the present invention. Referring to FIG. 2, a plurality of device isolation regions 101 and 101a and an active region are defined in a semiconductor substrate 100 of the EEPROM device. A first electrode layer 103 is formed in the device isolation region 101a, and the other device isolation region 101 is filled with an isolation insulating layer 102. Junction regions 104a and 104b are formed at both sides of the device isolation region 101a.

A gate insulating film 105 is formed on an entire surface of the semiconductor substrate. The gate insulating film 105 is partially etched to form a tunnel oxide film 106. Second electrode layers 107a and 107b are formed to overlap the first electrode layer 103 and the active region.

The second electrode layer 107a formed above the first electrode layer 103 is a floating gate, and the other second electrode layer 107b is an access gate.

In FIG. 2, the floating gate 107a and the regions 103, 104a and 104b formed below the floating gate 107a serve as a sense transistor. The access gate 107b spaced apart from the floating gate 107a and the junction region 104b below and around the access gate 107b serve as an access transistor.

As shown in FIG. 2, in the EEPROM device according to an exemplary embodiment of the present invention, the first electrode layer 103 that is a polysilicon layer is formed in at least one device isolation region 101a of the plurality of device isolation regions 101 and 101a. Therefore, the first electrode layer 103 may be used as a control gate.

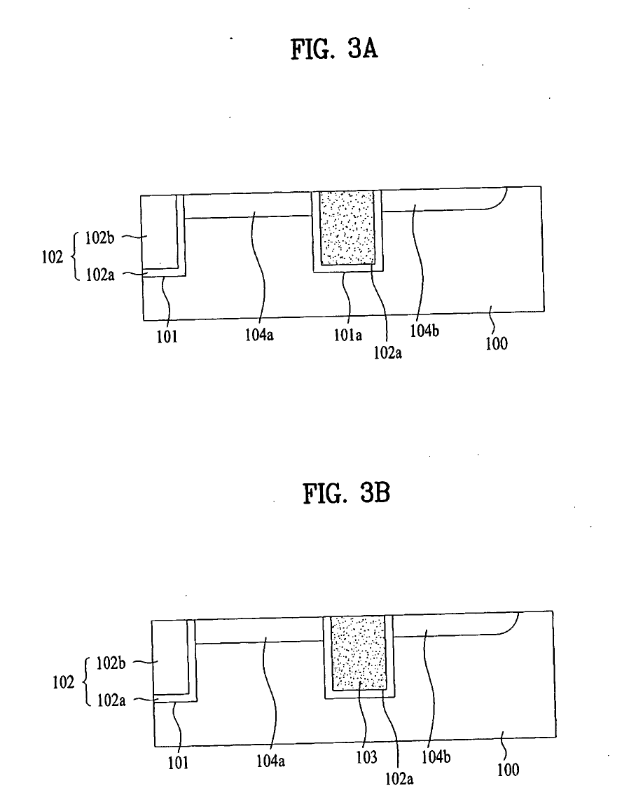

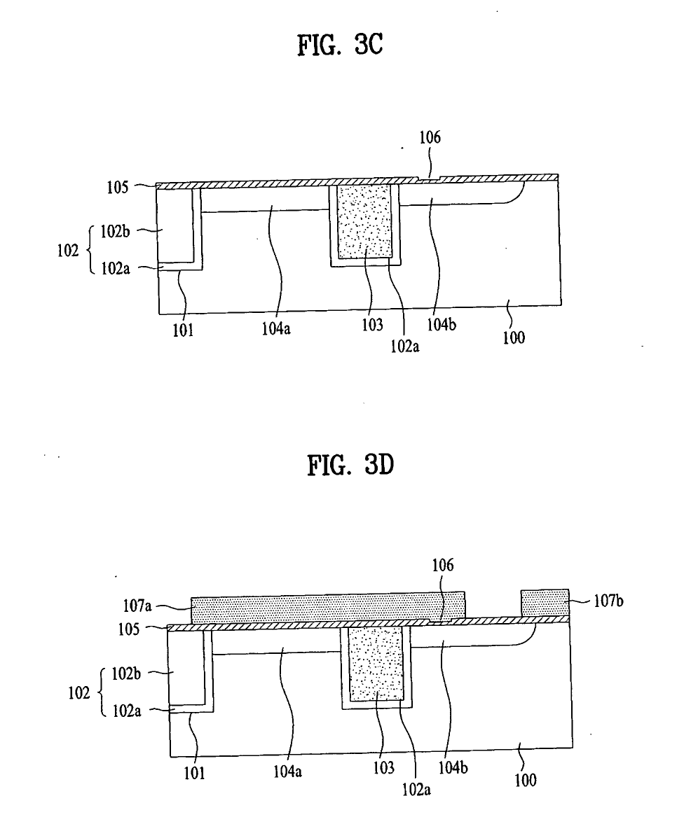

Hereinafter, a method for fabricating the EEPROM device shown in FIG. 2 will be described in detail with reference to FIG. 3A to FIG. 3D.

FIG. 3A to FIG. 3D are sectional views illustrating a method for fabricating the EEPROM device according to embodiment of the present invention.

First, as shown in FIG. 3A, a substrate 100 is prepared, in which a first type well, for example, a P type well is defined. After a predetermined region of the substrate 100 is etched by a local oxidation of silicon (LOCOS) process or a shallow trench isolation (STI) process to form a trench region, a nitride film (SiN) 102a is thinly formed inside the trench region. Subsequently, an oxide film 102b is formed on an entire surface of the semiconductor substrate 100 and then planarized by a chemical mechanical polishing (CMP) process or an etch-back process. The trench region is filled with the oxide film 102b to form device isolation regions 101 and 101a. A region outside of the device isolation regions is defined as an active region.

Subsequently, second type ions, for example, N+ type ions are implanted into a predetermined portion of the active region using a predetermined mask (not shown) to form junction regions 104a and 104b. The mask used for ion implantation is then removed, and the semiconductor substrate 100 is annealed to activate the ions implanted into the junction regions 104a and 104b.

Next, an oxide film 102 filled in at least one device isolation region 101a of the device isolation regions 101 and 101a is removed. Then, the portion where the oxide film 102 is removed is filled with an electrode material such as polysilicon to form a first electrode layer 103. At this time, after the electrode material is deposited on the semiconductor substrate 100, including the device isolation regions 101 and 101a, the first electrode layer 103 is filled in the device isolation region 101a using a CMP process or an etch-back process. The first electrode layer 103 filled in the device isolation region 101a is used as a control gate.

Afterwards, a gate insulating film 105 is deposited on the semiconductor substrate 100 at a predetermined thickness. At this time, second type ions, for example, N+ type ions can be implanted into the first electrode layer 103.

Subsequently, a predetermined portion of the gate insulating film 105 is selectively wet-etched to form a tunnel oxide film 106. Then, polysilicon is deposited on the gate insulating film 105, including the tunnel oxide film 106, and then selectively etched to form second electrode layers 107a and 107b. The second electrode layer 107a overlapped with the first electrode layer 103 serves as a floating gate, and the other second electrode layer 107b serves as an access gate. The floating gate 107a can be formed to cover the tunnel oxide film 106.

Next, second type ions, for example, N+ type ions are implanted into the second electrode layers 107a and 107b.

The EEPROM device fabricated as above is operated as follows.

In FIG. 2, the floating gate 107a and the regions 103, 104a and 104b formed below the floating gate 107a serve as a sense transistor. The access gate 107b spaced apart from the floating gate 107a and the junction region 104b below and around the access gate 107b serve as an access transistor.

First, an erasing operation will be described. A threshold voltage Vth of the sense transistor becomes positive (+) to turn a channel off as electrons are implanted into the sense transistor through the tunnel oxide film 106 by a floating gate voltage Vfg. The floating gate voltage Vfg is determined by a ratio of capacitance between the floating gate 107a and the junction regions 104a and 104b overlapped with the floating gate 107a, and every capacitance overlapped with the floating gate 107a.

Programming operation will now be described. If the access transistor is turned on to apply a voltage to a source junction region, ejection or hole injection of electrons charged due to the difference between the floating gate voltage derived from the floating gate 107a and the voltage transferred to the source junction region occurs. In this case, the threshold voltage Vth of the sense transistor becomes negative (−). In other words, the channel is turned on.

At this time, to lower a program threshold voltage Pgm Vt, a negative voltage may be applied to the first electrode layer 103 serving as the control gate.

Although an erasing line is formed of an active region in the related art EEPROM device, the portion filled with polysilicon among the device isolation regions is electrically operated to perform programming, as well as erasing, in the EEPROM device of the present invention. Therefore, in the present invention, it is possible to reduce the cell size to the maximum range in the process of the same line width as that of the related art.

Further, since the predetermined device isolation region is filled with polysilicon, a self-align process can be performed so that unnecessary exposure can be omitted. Thus, it is possible to reduce an unnecessary margin generated during exposure.

Further, in the present invention, in case where the device isolation region filled with polysilicon is used as an acceleration line, the positive voltage or the negative voltage is freely applied. Therefore, it is possible to reduce the junction regions.

As described above, the EEPROM, the method for fabricating the same, and the method for programming/erasing data in the same according to the present invention have at least the following advantages.

First, even if high voltage is applied to the control gate defined by the polisilicon filled in the device isolation region during erasing operation, no leakage path exists.

Second, since the device isolation region is filled with polysilicon to serve as electrode, the floating gate voltage can be defined to obtain a high coupling ratio. In this case, it is possible to reduce the erasing voltage. The junction region can be annealed at a low temperature for a short time as the erasing voltage is reduced.

Third, although the device isolation regions and the active region are separately defined in a conventional cell structure, at least one device isolation region is filled with the electrode material so that erasing or programming can be performed in the device isolation region as well as the active region. In this case, it is possible to reduce a BN line width in the erasing line.

Finally, since the negative voltage is applied to the electrode material filled in the device isolation region, even in case of programming, the voltage level through the access transistor becomes lower than the voltage level in the related art so as to lower the depth of the drain or source junction region in the access transistor and reduce the channel length of the transistor.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A nonvolatile memory device comprising:
a semiconductor substrate having a plurality of device isolation regions, including a first device isolation region and a second device isolation region, and an active region;
a first electrode layer formed in the first device isolation region of the plurality of device isolation regions;
an isolation insulating layer filled in the second device isolation region of the plurality of device isolation regions;
junction regions formed in a predetermined portion of the active region;
a gate insulating film formed on the semiconductor substrate, including the plurality of device isolation regions and the junction regions;
a tunnel oxide film formed by selectively etching the gate insulating film; and
a second electrode layer formed on the gate insulating film to partially overlap the junction regions.

2. The nonvolatile memory device as claimed in claim 1, wherein the second electrode layer includes a floating gate formed on the gate insulating film to overlap the first electrode layer and the junction regions, and an access gate formed on the gate insulating film spaced apart from the floating gate and partially overlapping the junction regions.

3. The nonvolatile memory device as claimed in claim 2, wherein the floating gate, the junction region overlapped with the floating gate, and the first electrode layer form a sense transistor.

4. The nonvolatile memory device as claimed in claim 2, wherein the access gate and the junction region overlapped with the access gate form an access transistor.

5. The nonvolatile memory device as claimed in claim 2, wherein the floating gate is formed on the gate insulating film to cover the tunnel oxide film.

6. The nonvolatile memory device as claimed in claim 1, wherein the first electrode layer forms a control gate.

7. A method for fabricating a nonvolatile memory device comprising:
forming a plurality of device isolation regions by selectively etching a predetermined portion of a semiconductor substrate so as to define the plurality of device isolation regions and an active region, the plurality of device isolation regions including at least first and second device isolation regions;
forming a first electrode layer by filling polysilicon in the first device isolation region of the plurality of device isolation regions;
filling an isolation oxide film in the second device isolation region;
forming junction regions in a predetermined portion of the active region;
forming a gate insulating film on the semiconductor substrate, including the plurality of device isolation regions and the junction regions;
forming a tunnel oxide film by selectively etching the gate insulating film; and
forming a second electrode layer on the gate insulating film.

8. The method as claimed in claim 7, wherein the step of forming the second electrode layer includes depositing an electrode material on the gate insulating film; and selectively removing the gate insulating film partially overlapped with the junction region and the first electrode layer to form the second electrode layer.

9. The method as claimed in claim 8, wherein the second electrode layer overlapped with the first electrode layer and the junction region is formed to cover the tunnel oxide film.

10. The method as claimed in claim 7, wherein the step of forming the gate insulating film includes implanting ions into the polysilicon that forms the first electrode layer.

11. A method for programming/erasing data in a nonvolatile memory device, the nonvolatile memory device comprising a semiconductor substrate defined by a plurality of device isolation regions and an active region, the plurality of device isolation regions including at least first and second device isolation regions, a first electrode layer formed in the first device isolation region of the plurality of device isolation regions, an isolation insulating layer filled in the second device isolation region of the plurality of device isolation regions, junction regions formed in a predetermined portion of the active region, a gate insulating film formed on the semiconductor substrate including the plurality of device isolation regions and the junction regions, a tunnel oxide film formed by selectively etching the gate insulating film, and a second electrode layer formed on the gate insulating film to partially overlap the junction regions, the method comprising using the first electrode layer as an acceleration line so that a negative voltage or a positive voltage is applied to the first electrode layer to program or erase predetermined data.
